(19) United States
(12) Patent Application Publication
(10) Pub. No.: US 2022/0074057 A1
(43) Pub. Date: Mar. 10, 2022

(54) SYSTEMS AND METHODS FOR LARGE SCALE GAS GENERATION

(71) Applicant: Utica Leaseco, LLC, Rochester Hills, MI (US)

(72) Inventors: Sateria SALIM, San Jose, CA (US); Kuanping GONG, Union City, CA (US); Daniel Mark DOBKIN, Sunnyvale, CA (US); Nabil A. KHATER, San Jose, CA (US)

(21) Appl. No.: 17/472,106

(22) Filed: Sep. 10, 2021

Related U.S. Application Data
(60) Provisional application No. 63/076,615, filed on Sep. 10, 2020.

(51) Int. Cl. C25B 1/01; C23C 16/30; C23C 16/448; C25B 1/50; C25B 15/08; C25B 11/04; C25B 11/02

(52) U.S. Cl. CPC C25B 1/01; C23C 16/301; C23C 16/448; H01L 21/02546; C25B 15/08; C25B 11/04; C25B 11/02; C25B 1/50

(57) ABSTRACT

A system and method for generating gas are disclosed. The system may include one or more current sources to generate an electrical current. The system may also include one or more cathode-anode assemblies electrically coupled with the one or more current sources. The one or more cathode-anode assemblies may generate a gas in response to receiving the electrical current from the one or more current sources. Each of the one or more cathode-anode assemblies may include a first electrode and a second electrode forming a concentric cylindrical structure, wherein the second electrode surrounds the first electrode and forms a gap between the second electrode and the first electrode. The system may also include electrolyte provided in the gap.

### CROSS-REFERENCE TO RELATED APPLICATION(S)

This application claims the benefit of U.S. Provisional Application No. 63/076,615, entitled “Systems and Methods for Large Scale Gas Generation” and filed on Sep. 10, 2020, which is expressly incorporated by reference herein in its entirety.

### BACKGROUND

### Technical Field

The present disclosure relates generally to generating gases for semiconductor processing operations, and more particularly, to systems and methods for gas generation.

### INTRODUCTION

Arsine (AsH3), in the form of arsine gas, may be employed for growth of gallium-arsenide (GaAs) and other compound semiconductors by metal-organic chemical vapor deposition (MOCVD). Techniques for synthesis of arsine include aqueous reduction of various arsenic compounds, and extensive purification thereafter. These techniques typically use a gas manufacturing facility separate from arsine utilization facilities (e.g. semiconductor manufacturing facility). Typically, arsine gas is supplied from the gas manufacturing facility in pressurized cylinders. The highest risk in handling arsine may occur during the transportation of the pressurized cylinders between the gas manufacturing facility and the utilization facilities due to the use of fork lifts, transport trucks and dollies. For example, accidental release of arsine from a pressurized cylinder may occur through a valve shearing during the transport of the pressurized cylinder which may cause a lethal dose of the gas to escape.

Accordingly, there exists a need for further improvements to systems and methods for arsine generation.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

In an aspect, a gas generator is presented. The gas generator may include one or more current sources configured to generate an electrical current. The gas generator may also includes one or more cathode-anode assemblies electrically coupled with the one or more current sources and configured to generate a gas in response to receiving the electrical current from the one or more current sources, wherein each of the one or more cathode-anode assemblies comprises a first electrode and a second electrode forming a concentric cylindrical structure having a first opening and a second opening at distal ends of the concentric cylindrical structure, wherein the second electrode surrounds the first electrode and forms a gap between the second electrode and the first electrode, wherein the one or more cathode-anode assemblies are oriented in the gas generator for the gas to rise vertically through the gap from the first opening to the second opening. The gas generator may also include electrolyte configured to circulate through the gap of the one or more cathode-anode assemblies.

In an aspect, a cathode-anode assembly is presented. The cathode-anode assembly may be configured to be implemented in a gas generator capable of holding the cathode-anode assembly. The cathode-anode assembly may include a first electrode that forms a first elongated cylindrical structure. The cathode-anode assembly may also include a second electrode that forms a second elongated cylindrical structure concentric with the first electrode, wherein a gap is formed between the second electrode and the first electrode, wherein the gap allows circulation of electrolyte within the cathode-anode assembly, and gas is generated in the gap in response to an electrical current being applied to the cathode-anode assembly.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIG. 1A illustrates a chart of an example for approximating the generation of arsine, according to aspects of the present disclosure;

FIG. 1B illustrates a chart of an example of estimating mass-transport-limited operation in a non-circulating electrolyte system;

FIG. 1C illustrates a chart of an example of estimating depletion thickness at mass-transport-limited operation in a non-circulating electrolyte system;

FIG. 2 illustrates an example of a gas generating system, according to aspects of the present disclosure;

FIG. 3 illustrates an example of a gas generator incorporated by the system of FIG. 2, according to aspects of the present disclosure;

FIG. 4 illustrates another example of a gas generator incorporated by the system of FIG. 2, according to aspects of the present disclosure;

FIG. 5 illustrates an example of a top-down view of a cathode-anode assembly incorporated by the system of FIG. 2, according to aspects of the present disclosure;

FIG. 6 illustrates an example of a side view of the cathode-anode assembly of FIG. 5, according to aspects of the present disclosure;

FIG. 7 illustrates an example of a gas collector incorporated by the system of FIG. 2, according to aspects of the present disclosure; and

FIG. 8 illustrates an example of a method of generating gas, according to aspects of the present disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

As described herein, gas generation techniques typically use a gas manufacturing facility separate from arsine utilization facilities (e.g. semiconductor manufacturing facility) gas manufacturing facilities. Some techniques have been used to address safety and efficient utilization of consumable arsenic cathodes, but are unsuitable for high-rate gas generation at rates an order of magnitude or more greater than those typically achieved. For example, U.S. Pat. No. 8,021,536 to Machado et. al. describes an arsine generator. The generator configuration described by Machado et. al. employs a current density of approximately 14 mA/cm² on the cathode and 9 mA/cm² on the anode surface, when initiating a gas generation process. In order to support the generation of 5 standard liters per minute (0.22 mol/minute) of arsine at 90% efficiency, a total current of about 1200 A is required by the gas generator described by Machado et al. At the current density described above, the gas generator described by Machado et al. would require an area of 8.7 m². Employing the arsenic rod diameter of 3.8 cm described therein, the rod height would be 73 meters. If more practical arsenic rods of 0.5 m height were employed, 146 rods would be required. Since the anode and cathode must be in close proximity to avoid excessive electrolyte voltage, 146 individual cathode/anode cells would be needed, leading to impractical complexity. Therefore, the starting current density must be increased by an order of 10-20 times for a manufacturable high-volume generator.

In order to operate at higher current density, the typical gas generator design is not suitable. Instead, a gas generator design that supports continuous uniform circulation of the electrolyte, as is demonstrated by the following calculation. At the anode surface, the following reaction takes place:

Mo+8 OH⁻→MoO₄²⁻+4 H₂O+6e⁻

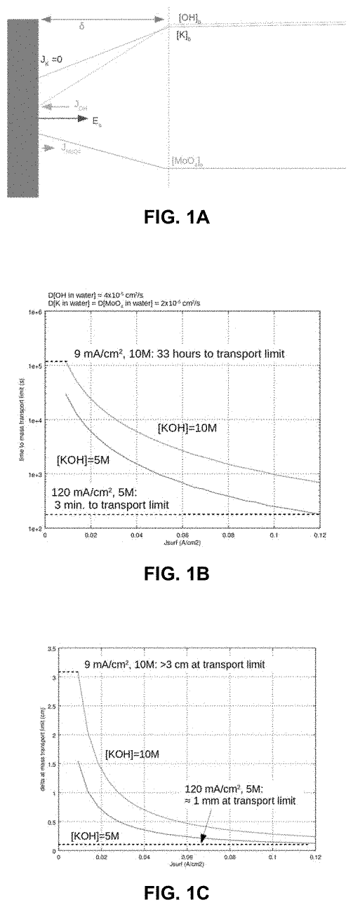

In some examples, two molecules of arsine are produced by the six electrons released, so that one hydroxyl ion is consumed for each arsine molecule produced, and one molybdate ion is produced for each pair of arsine molecules. Since hydroxide is consumed at the surface, the concentration in the electrolyte near the electrode surface may be reduced relative to the average concentration in the electrolyte, while molybdate accumulates. Gradients in concentration of the relevant ionic species, and corresponding electric fields, will arise near the surface. The situation may be simply approximated assuming that concentrations are linear in distance from the surface over some depleted layer of width 6, as depicted by FIG. 1A. Here δ is a function of time for constant current conditions, and is determined by balancing consumption of species at the surface with the amount used in the depleted layer.

When a distance over which the diffusing species must travel becomes excessive, large changes in concentration may occur near the anode surface. Such changes may have various deleterious effects, including increases in voltage and thus power consumption and heating, and the possibility of oxygen generation, which may result in contamination of a generated gas stream. For example, the following equations discuss the transport of hydroxide ions to a surface, and consequent molybdate ions transported away from the surface, where the positive potassium ions do not react, and therefore the net current for those ions are equal to zero.

$$Zero consumption of potassium \text{:} {μ}_{K} F {K}_{s} {E}_{x} - {D}_{K} \frac{{K}_{b} - {K}_{s}}{δ} = 0$$

$$Charge neutrality at the surface \text{:} {K}_{s} = {MoO}_{s} + {OH}_{s}$$

$$Flux at surface from electric current \text{:} \\ - {μ}_{OH} F O {H}_{S} {E}_{x} - {D}_{O H} \frac{O {H}_{b} - O {H}_{s}}{δ} = \frac{4}{3} \frac{{J}_{elec}}{F} and \\ - {μ}_{M o O} F M o {O}_{s} {E}_{x} - {D}_{M o O} \frac{M o {O}_{b} - M o {O}_{s}}{δ} = \frac{1}{6} \frac{{J}_{elec}}{F}$$

where D_{K} is an effective binary diffusion for potassium ions (and similarly D_{OH} for hydroxyl ions, D_{MoO} for molybdate ions), F is the Faraday constant (i.e., 96480 Coulombs/mole), and Kₛ, OHₛ, and MoOₛ are the surface concentrations of potassium, hydroxyl, and molybdate ions respectively, with the subscript b indicating the bulk concentrations. An electric field must arise to ensure that the current of potassium ions is zero:

$${E}_{x} = {D}_{K} \frac{{K}_{b} - {K}_{s}}{{μ}_{el} {K}_{s} δ}$$

The solution of the set of simultaneous equations shown will produce an estimate of the surface concentrations of the various species for a given depleted layer thickness, and a corresponding time to reach that thickness. When the predicted value of hydroxyl ion concentration at the surface nears 0, the reaction is expected to become mass-transport-limited, with deleterious consequences described herein.

An estimate of the resulting time to encounter mass-transport-limited operation in a non-circulating electrolyte is depicted in FIGS. 1B and 1C. In FIG. 1B, a graph of time to mass transport limit vs. surface current density is depicted, and in FIG. 1C, a graph of depletion thickness at mass transport limit vs. current density is depicted. For the operating conditions described above, with anode current density of about 9 mA/cm², the times involved are on the order of 100,000 seconds (e.g., more than 1 day) for the starting KOH concentration described by Machado et. al., with the corresponding depleted regions more than 1 cm thick, comparable to the dimensions of the gas generator. Only minimal circulation, as expected from bubbling at the cathode and natural convection, is needed to maintain reasonable concentration uniformity and allow unimpeded operation.

In contrast, at current density of greater than 100 mA/cm² required for practical high-volume generation, particularly with lower KOH concentrations (which provide higher electrical conductivity appropriate for high current density) depletion times are on the order of seconds to minutes, with depleted regions on the order of 1 mm thick. Without continuous uniform circulation of the electrolyte, depletion of reactants and accumulation of products at the anode surface will result in times comparable to the process time for a wafer run, leading to various deleterious results including increased overvoltage, creation of insoluble molybdenum suboxides, and possible evolution of oxygen, the last being very undesirable in the production of high purity gases. The use of continuous circulation may ensure that fresh chemical precursors are readily available at the surface of the anode, and that byproducts of the reaction are readily flushed away from the electrode surfaces, with optional removal from the electrolyte in the circulation system.

Note the estimates presented here are rough approximations, not attempting to incorporate the full complexity of partially-dissociated mixed neutral/charged species transport in the high-concentration electrolyte, or account for partially-oxidized product species. However, the general behavior shown may be relied upon for guidance in design of the gas generator disclosed herein: as current density is increased, mass transport limitations are expected to arise rapidly.

In order to overcome the limitations of a typical gas generator and implement a practical high-volume arsine gas generator, the present disclosure uses a concentric electrodes to ensure uniformity of flow and provisions for continuous circulation of electrolyte to assist bubble-driven flow at the cathode.

In particular, the present disclosure describes cost effective and efficient systems and methods of generating arsine (AsH3) gas by electrochemical generation. The systems, as described herein, may be used as a safer alternative to the storage and the delivery of arsine gas. In an example, arsine gas may be generated from solid arsenic by applying an electrical current to an electrochemical cell. Arsenic may be a solid source and several order of magnitude safer and easier to handle than a high pressure cylinder containing arsine. According to aspects of the present disclosure, arsine gas may be generated as needed at an arsine utilization facility (e.g., semiconductor manufacturer facility) and confined in a gas storage system within a metal-organic chemical vapor deposition (MOCVD) supply system.

Further, to reduce operating costs, an electrochemical cell may be designed to result in a high utilization of arsenic starting materials. This may not only reduce the cost of raw materials but also increase an up-time of electrochemical cells utilizing aspects of the present disclosure. For example, the present disclosure describes a unique geometric design that may allow efficient utilization of arsenic material. In an example, an optimal design of a cathode-anode assembly may be used to increase efficient arsenic material in the electrochemical cells. The design may also decrease the operating cost and preserve the electrochemical cell efficiency to produce arsine gas.

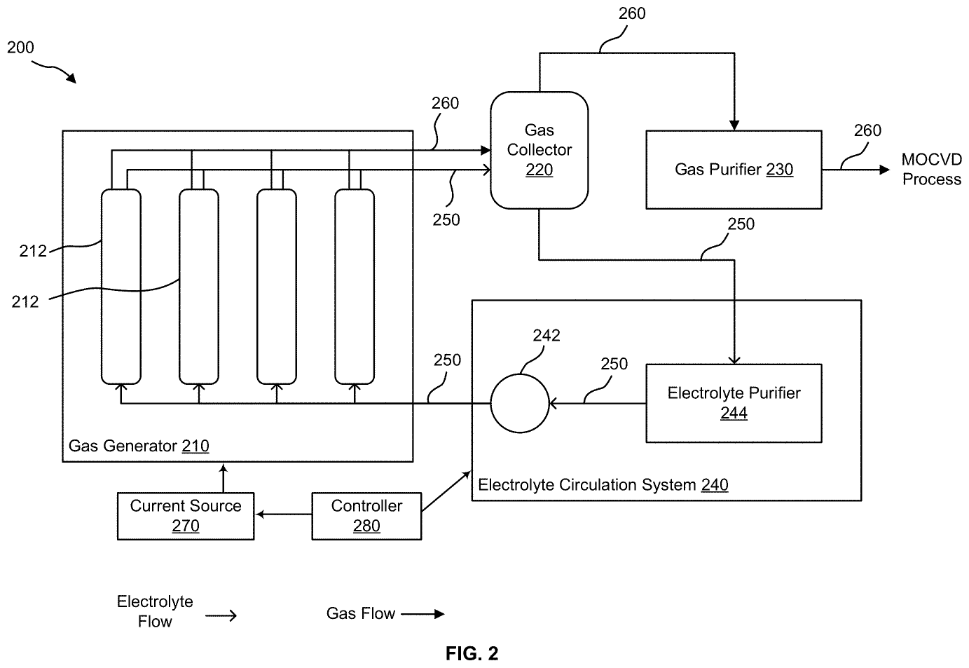

Referring to FIG. 2, an example of a gas generating system 200 is depicted, along with examples of a flow of electrolyte 250 and a flow of gas 260 (e.g., arsine) through the gas generating system 200. One skilled in the art would recognize that different arrangements of the components and/or additional components included in the gas generating system 200 may affect the flow of the electrolyte 250 and the gas 260.

In an aspect, the gas generating system 200 is configured to generate and provide gas (e.g., arsine) to an MOCVD process. In an example, the gas generating system 200 may include a gas generator 210 configured to generate the gas. The gas generator 210 may include one or more cathode-anode assemblies 212, described in further detail herein, that generate the gas based on an electrical current being applied to the one or more cathode-anode assemblies 212.

The gas generating system 200 may also include a gas collector 220 configured to collect the generated gas from the gas generator 210, and a gas purifier 230 configured to purify the gas and provide the purified gas to the MOCVD system. In an example, and as described in more detail herein, the gas collector 220 may receive the electrolyte 250, the gas 260, and/or gas bubbles from the gas generator 210.

The gas generating system 200 may also include a gas purifier 230 configured to purify the gas 260 by removing contaminants from the gas 260. The gas purifier 230 may provide the purified gas 260 to the MOCVD system.

The gas generating system 200 may also include an electrolyte circulation system 240 configured to circulate the electrolyte 250 through the gas generator 210. The electrolyte circulation system 240 may include a pump 242 configured to circulate the electrolyte 250 through the cathode-anode assemblies 212 of the gas generator 210. In an example, the pump 242 may provide the electrolyte 250 to a first distal end (or bottom side) of the cathode-anode assemblies 212 and pull the electrolyte 250 from a second distal end (or top side) of the cathode-anode assemblies 212. In an example, the pump 242 may be electrically driven and controlled to avoid use of rotating seals, or the pump 242 may include a magnetically-coupled pump.

In an aspect, the gas collector 220 may receive the electrolyte 250 and provide the electrolyte 250 to a electrolyte purifier 244 of the electrolyte circulation system 240. In an example, the electrolyte purifier 244 may be configured to remove contaminants from the electrolyte 250 that were received in the cathode-anode assemblies 212 and/or the gas collector 220. For example, the electrolyte purifier 244 may include a particle filter, an ion-exchange, and/or any other similar purification system for removal of contaminants such excessive amounts of molybdenum oxide compounds from the electrolyte 250. The electrolyte purifier 244 may also include gas sources for purging the electrolyte 250 to remove residual gas 260 (e.g., arsine), for example, in preparation for an exchange of used cathode-anode assemblies 212 for new cathode-anode assemblies 212.

In some examples, the electrolyte circulation system 240 may also control a temperature of the electrolyte 250. For example, the electrolyte circulation system 240 may include a heater or cooler (not shown) which heats or cools the electrolyte 250 to provide an optimal temperature for the generation of the gas 260 and maintenance of the cathode-anode assemblies 212 and/or any other component of the gas generating system 200.

The electrolyte circulation system 240 may also be configured to maintain control of composition of the electrolyte 250. For example, the electrolyte circulation system 240 may include a reservoir (not shown) of concentrated potassium hydroxide, from which one or more additives are drawn as needed to maintain a pH level or electrolyte concentration of the electrolyte 250 being circulated through the gas generating system 200. In an example, the electrolyte circulation system 240 may also provide surfactants, alternative bases such as LiOH, to the electrolyte 250 before being provided to the gas generator 210.

In an example, the electrolyte 250 may be formed of an alkaline solution potassium hydroxide (KOH) or sodium hydroxide (NaOH). Further, the electrolyte 250 may optionally contain various additives to optimize performance in generating the gas 260. The electrolyte 250 may provide temperature control of the cathode-anode assembly 212 and remove contaminants, generated during the operation of the gas generator 210, as explained in more detail herein.

In an aspect, the gas generating system 200 may also include a current source 270 to provide an electrical current to the cathode-anode assemblies 212. However, in other examples, the gas generating system 200 may include a plurality of current sources 270 having a one-to-one relationship or a one-to-many relationship of current sources 270 to cathode-anode assemblies 212 (e.g., 1 current source 270 to 4 cathode-anode assemblies 212).

The gas generating system 200 may also include a controller 280 electrically coupled with and configured to control one or more components of the gas generating system 200 including the electrolyte circulation system 240, the current source 270, and/or the gas purifier 230.

Referring to FIGS. 2-5, an example of a cathode-anode assembly 212 installed in the gas generator 210 is depicted. In an aspect, the cathode-anode assembly 212 may form an elongated structure such that distal ends of the cathode-anode assembly 212 are positioned vertically or perpendicular to a plane of the Earth (or substantially parallel to a general rising direction of gas bubbles 360 that result from a electrochemical reaction) within the gas generator 210.

In an aspect, the cathode-anode assembly 212 may be supported by support structures of the gas generator 210 including a housing 302 that surrounds the one or more cathode-anode assemblies 212 and a cap 304 and a base 306 which support the cathode-anode assemblies 212.

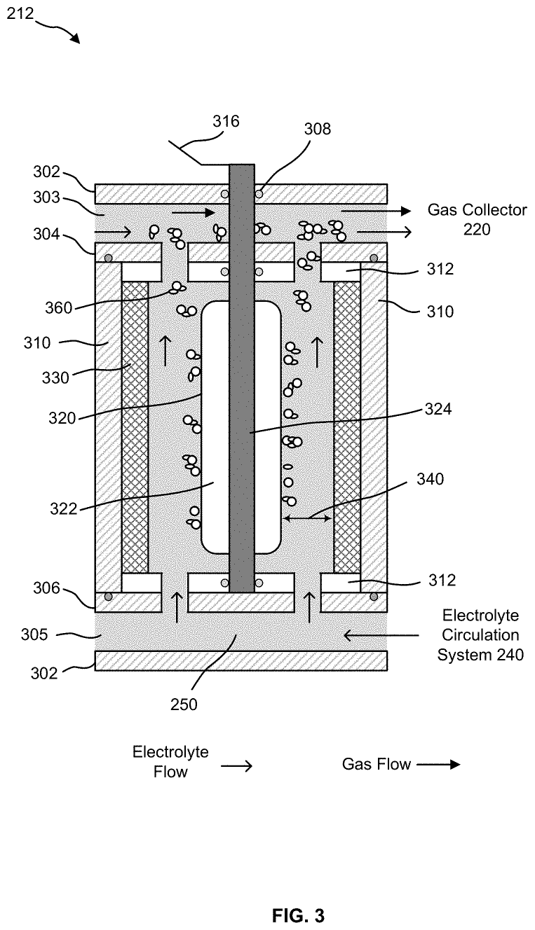

As depicted by FIG. 3, an outlet tray 303 may be formed from a space between the housing 302 and the cap 304. The outlet tray 303 may capture the electrolyte 250 and the gas 260 (including gas bubbles 360) exiting the cathode-anode assembly 212 and provide the electrolyte 250 and the gas 260 (including gas bubbles 360) to the gas collector 220. The outlet tray 303 may be spaced such that an expected level of the electrolyte 250 reaches a surface of the housing 302. This spacing of the outlet tray 303 may provide a space in which the gas 260 and gas bubbles 360 may accumulate in the electrolyte 250 and be provided to the gas collector 220 for separation of the gas 260 and the electrolyte 250.

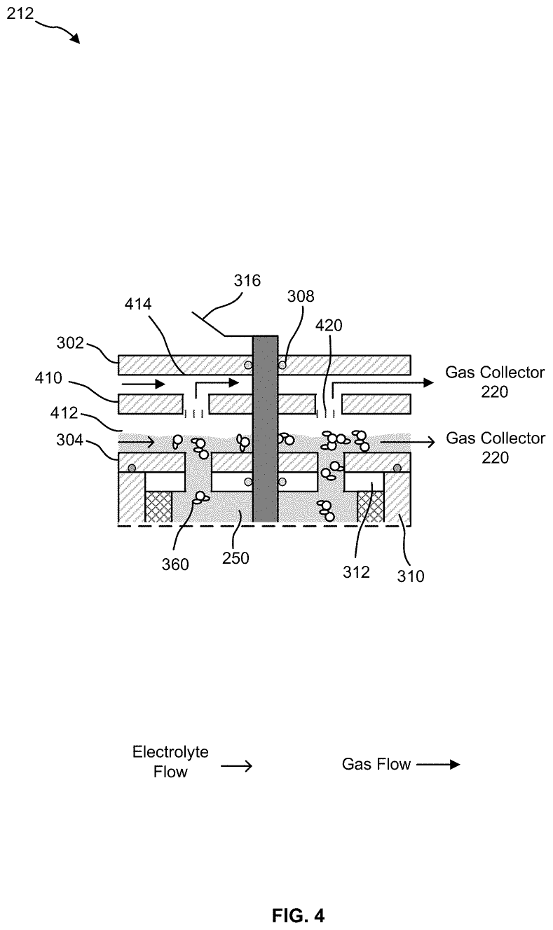

As depicted by FIG. 4, in some aspects, the gas generator 210 may include separate outlets for the electrolyte 250 and the gas 260. For example, gas generator 210 may include a separator 410 positioned between the housing 302 and the cap 304, which form a capture tray 412 and a gas outlet tray 414. In this example, the capture tray 412 may be formed from a space between the cap 304 and the separator 410. The capture tray 412 may capture the electrolyte 250 and the gas 260 (including gas bubbles 360) exiting the cathode-anode assembly 212 and provide the electrolyte 250 to the gas collector 220. The spacing of the capture tray 412 may provide an area in which the gas 260 and the gas bubbles 360 may accumulate and separate from the electrolyte 250. For example, the capture tray 412 may allow arsine and hydrogen gas to separate from the electrolyte 250.

The gas outlet tray 414 may be formed from a space between the separator 410 and the housing 302. The gas outlet tray 414 may capture gas 260 that exits the capture tray 412, via one or more openings in the separator 410, and provide the gas 260 to the gas collector 220. As shown by FIG. 2, the gas outlet tray 414 may be shared with each of the cathode-anode assemblies 212. However, in other examples, each cathode-anode assembly 212 may have an individual gas outlet tray 414.

In some examples, one or more demisting devices 420 may be provided in openings between the capture tray 412 and the gas outlet tray 414 to remove moisture from the gas 260 (e.g., assist in popping the gas bubbles 360) as the gas 260 enters the gas outlet tray 414.

In another example, an inlet tray 305 may be formed from a space between the housing 302 and the base 306. The inlet tray 305 may receive the electrolyte 250 from the electrolyte circulation system 240 and provide the electrolyte 250 to the cathode-anode assembly 212. As shown by FIG. 2, the inlet tray 305 may be shared with each of the cathode-anode assemblies 212. However, in other examples, each cathode-anode assembly 212 may have an individual inlet tray 305.

In an aspect, the cathode-anode assembly 212 may include a support wall 310 positioned between the cap 304 and the base 306. In an example, the support wall 310 may be formed of a conductive material such as stainless steel. The support wall 310 may couple with the housing 302 of the gas generator 210, which is electrically grounded. The cathode-anode assembly 212 may also include electrical insulators 312 coupled with the cap 304 and the base 306 of the gas generator 210.

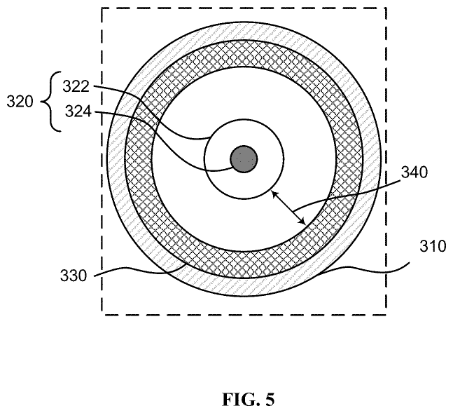

In an aspect, the cathode-anode assembly 212 may also include a first electrode 320 and a second electrode 330. In an example, the first electrode 320 may be a sacrificial cathode, or a cathode that is consumed during generation of gas, such as arsine (AsH₃)(i.e., during operation of the gas generator 210). In an example, the first electrode 320 may form an elongated structure that is cylindrical, and/or form a concentric cylindrical structure, as depicted by FIG. 5.

The first electrode 320 may include a first electrode layer 322 attached to a support rod 324. The first electrode layer 322 may be formed of elemental arsenic (As), and may be formed by being deposited into a concentric matter around at least a portion of the support rod 324.

The support rod 324 may be formed of a highly electron conductive material such as steel, iron, stainless steel, tungsten, or any conductive material stable in a an alkaline environment. In an example, the support rod 324 may extend the length of the first electrode layer 322 and, in some examples, past one or more ends of the first electrode layer 322, as shown by FIG. 3. As described herein, the support rod 324 may receive an electrical current from a current source (not shown) via an attached electrical contact 316 attached at a first end of the support rod 324 and distribute the electrical current uniformly along the first electrode 320. In other examples, the support rod 324 may receive electrical current from a second end of the support rod 324.

In an example, the support rod 324 may extend through the housing 302 and the cap 304 of the gas generator 210, and through the electrical insulators 312 of the cathode-anode assembly 212. One or more gaskets 308 may be positioned between the support rod 324 and one or more of the housing 302, the electrical insulators 312, or another material or layer to prevent leakage of electrolyte 250 and/or gas 260 from the cathode-anode assembly 212 and the gas generator 210.

In an example, any exposed surfaces of the support rod 324 may be covered by a polymeric coating, such as polytetrafluoroethene (PTFE), or other means for corrosion or hydrogen evolution due to the electrolyte 250.

The second electrode 330 may be an elongated, cylindrical structure, and/or form a concentric cylindrical structure that surrounds the first electrode 320, as shown by FIG. 5. In other words, the second electrode 330 may have an inner diameter size that is greater that the outer diameter size of the first electrode 320. In an example, the second electrode 330 may be placed in a concentric manner with respect to the first electrode 320. In an example, one or more ends of the second electrode 330 may be positioned between the electrical insulators 312 of the cathode-anode assembly 212, as shown by FIG. 3. Further, the second electrode 330 may contact the support wall 310 to

In an example, the second electrode 330 may be a sacrificial anode, or an anode that oxidizes itself during generation of the gas 260, such as arsine (i.e., during operation of the gas generator 210). The second electrode 330 may be formed of an oxidizable material or metal such as molybdenum, tungsten, a hydrogen-oxidation anode, or any other material that may oxidize at a voltage less than a voltage at which oxygen would be evolved at an anode surface, and the resulting oxidized species area readily dissolved by the electrolyte 250.

The second electrode 330 may couple with and be supported by the support wall 310. In an example, the support wall 310 may provide an electrical connection to the second electrode 330. For example, the second electrode 330 may be electrically grounded through the support wall 310. In another example, one or more rods or wires (not shown) may couple with the second electrode 330 to provide an electrical connection (e.g., electrical grounding). The one or more rods or wires may be protected from contact with the electrolyte 250 to minimize corrosion of contact material.

In an aspect, ends of the second electrode 330 may be sealed to the electrical insulators such that only the inner surface of the second electrode 330 contacts the electrolyte 250.

As depicted by FIGS. 3 and 5, the first electrode 320 and the second electrode 330 may form a gap 340 between the outer surface of the first electrode 320 and the inner surface of the second electrode 330. The gap 340 may provide an area for the gas 260 and the gas bubbles 360 to be generated and a path for the electrolyte 250 to uniformly flow through the cathode-anode assembly 212.

In an example, a size of the gap 340 may be spaced to allow the gas 260 and the gas bubbles 360 to not interfere with the gas generation, spaced to prevent an increase in energy needed to generate the gas 260, and spaced to allow circulation of the electrolyte 250 through the cathode-anode assembly 212 for removal of contaminants produced during gas generation.

As shown by FIG. 2, the inlet tray 305 may receive the electrolyte 250 from the electrolyte circulation system 240, and may provide the electrolyte 250 to the cathode-anode assembly 212 via one or more openings into the gap 340. Further, the electrolyte 250 may flow vertically from a first distal end of the cathode-anode assembly 212 through the gap 340 and out of a second distal end of the cathode-anode assembly 212 via one or more openings between the gap 340 and the outlet tray 303. The flow of the electrolyte 250 may allow the gas bubbles 360 to rise along a natural path (vertically) while also renewing of electrode (e.g., anode) reactants and reduce gas bubble accumulation effects, particularly near the second distal end (e.g., top) of the cathode-anode assembly 212.

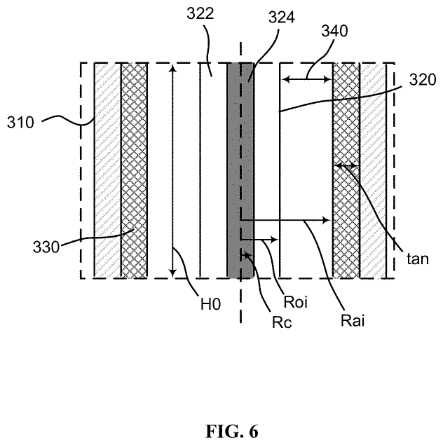

Referring to FIG. 6, a side view of a cathode-anode assembly 212 is depicted to facilitate in the description of how the dimensions of the first electrode 320 and the second electrode 330 may be obtained based on the considerations below. In the discussion below, the following notation is adopted, as depicted FIG. 6:

R_{c}=radius of the support rod 324;

Rₒᵢ=initial radius of the first electrode 320;

R_{0f}=final radius of the first electrode 320 when a maximum allowed consumption of the first electrode 320 is reached;

Hₒ=length of the first electrode 320 exposed to the electrolyte 250;

N_{rod}=number of cathode-anode assemblies 212 in a single gas generator 210;

MWT(AsH3)=molecular weight of arsine, approximately 77.95 g/mol;

MWT(As)=molecular weight of arsenic, approximately 74.92 g/mol;

Q(AsH₃)=total mass of arsenic that could be produced before cathode-anode assembly 212 replacement;

Fstd(AsH₃)=output flow of arsine in standard liters per minute;

RTP₀=conversion constant from standard liters per minute to moles per second, about 7.4×10⁻⁴;

Y(AsH₃)=percentage of AsH₃ in the produced mixture of AsH₃:H₂;

I_{gen}=total generation current provided to all the cathode-anode assemblies 212 of a single gas generator 210, where the current supplied to the various rods is treated as electrically in parallel;

nₑ=number of electrons required to produce an arsine molecule, 3 in this case; and

F=Faraday constant, approximately 96480 Coulombs/mole.

In an example, the largest quantity of arsine that may be produced by a gas generator 210 before replacement of the first electrode 320 (e.g., cathode) becomes necessary may be calculated by:

$$Q ( A s {H}_{3} ) [ kg ] = {ρ}_{A s} π ( {R}_{o i}^{2} - {R}_{of}^{2} ) {H}_{0} {N}_{rod} \frac{M W T ( A s {H}_{3} )}{M W T ( A s )}$$

The current required to produce a given output flow of arsine, assuming the yield Y is known, may be based on:

$${I}_{g e n} = {n}_{e} F {F}_{std} \frac{R T {P}_{0}}{Y ( A s {H}_{3} )}$$

The exposed surface area at the start of process with a new set of first electrodes 320 may be based on:

Aₛᵢ=2πRₒᵢH₀N_{rod}

and the corresponding surface area at the termination of processing with a given cathode-anode assembly 212 may be determined by:

A_{sf}=2πR_{of}H₀N_{rod}

The initial current density at the first electrode 320 may be calculated by:

$${J}_{c i} = \frac{{I}_{g e n}}{{A}_{si}}$$

at the initiation of processing with a new set of cathode-anode assemblies 212, and

$${J}_{c f} = \frac{{I}_{g e n}}{{A}_{s f}}$$

at the termination of processing with the cathode-anode assemblies 212.

The procedure for determining the dimensions of the cathode-anode assemblies 212 may then be based on the following operations. First, the constraints may be set on the design based on a final performance requirements. In an example, such requirements might be a maximum allowed size for the generator envelope based on the facility in which it will be installed, the largest arsenic samples a vendor can fabricate, the uptime requirements of the use facility, and the flow requirements of MOCVD processes. From these external limitations, one may obtain the maximum allowed length of a single cathode H_{c}, maximum allowed radius Rₒᵢ, required total output arsine before rod change Q(AsH₃), required output flow rate Fstd. Second, the maximum allowed current density may be established from experiment or simulation for a specific geometry in use an by measuring a arsine yield at that current density. Third, the required current I_{gen} may be established from Fstd for the arsine yield measured above.

Fourth, the number of cathodes N_{rod} may be determined from the requirement on Q(AsH₃), the allowed starting radius Rₒᵢ, and the maximum allowed value H_{c}. Fifth, the radius at which processing of the cathode set is terminated, R_{of}, may be determined from the current density constraint J_{cf}. Sixth, the core radius Re may be set to be slightly less than R_{of}, such as 90% of R_{of}. Seventh, the minimum electrolyte flow may be established. In an example, the minimum electrolyte flow is set to ensure replacement of the electrolyte 250 in a cathode-anode assembly 212 (on average) during the time the anode region would otherwise be depleted for the operating conditions noted above. Eighth, the inner diameter of the anode may be selected to create a channel sufficiently large at the initiation of processing with a new set of cathode-anode assemblies 212 to permit the target minimum electrolyte flow.

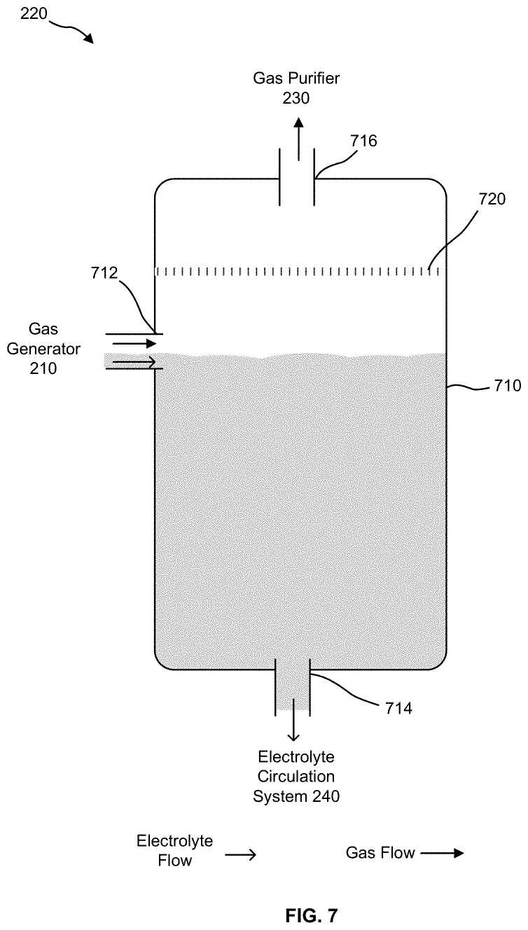

Referring to FIG. 7, an example of the gas collector 220 is depicted. As shown, the gas collector 220 may include a housing 710 having an inlet 712 coupled with the outlet tray 303. The inlet 712 may be configured to receive the electrolyte 250 and the gas 260 (and/or gas bubbles 360) from the gas generator 210. In another example, the housing may have multiple inlets coupled with the capture tray 412 and the gas outlet tray 414. The housing 710 may also include an electrolyte outlet 714 which is configured to provide the electrolyte 250 to the electrolyte circulation system 240. In an example, the electrolyte outlet 714 may be positioned at a base (or along a sidewall near the base) of the housing 710 to allow the electrolyte 250 to exit the housing 710 due to gravity. The housing 710 may also include a gas outlet 716 configured to provide the gas 260 to the gas purifier 230. In an example, the gas outlet 716 may be positioned at a top (or along a side wall near the top) of the housing 710, as shown by FIG. 7, to allow the gas 260 to exit along a natural rising path. In an example, the gas collector 220 may also include a demisting device 720 configured to remove moisture from the gas 260 (e.g., assist in popping the gas bubbles 360) as the gas 260 exits the gas collector 220.

Example of Operation of Gas Generator

During operation of the gas generator 210, the controller 280 may control the current source 270 to provide an electrical current to the one or more cathode-anode assemblies 212. For example, the current source 270 may provide the electrical current to the first electrode 320 (e.g., cathode) via the electrical contact 316, the electrical current may then flow from the first electrode 320 to the second electrode 330 (e.g., anode) via the gap 340, and to electrical ground via the support wall 310. Due to the provided electrical current, an electrochemical reaction may occur in the gap 340 between the material (e.g., elemental arsenic) of the first electrode layer 322 of the first electrode 320 and the material (e.g., molybdenum or tungsten) of the second electrode 330. The electrochemical reaction may produce a high yield of the gas 260 (e.g., arsine) in the gap 340.

Further, the electrolyte circulation system 240 may circulate the electrolyte 250 through the one or more cathode-anode assemblies 212 and the gas generator 210, as shown by FIGS. 2-4. In an example, the pump 242 may provide the electrolyte 250 to the base of the one or more cathode-anode assemblies 212 via the inlet tray 305. The pump 242 may push the electrolyte 250 into gap 340 at the first distal end (e.g., base) of the cathode-anode assemblies 212 via one or more openings between the inlet tray 305 and the cathode-anode assemblies 212.

As the gap 340 of the one or more cathode-anode assemblies 212 contain the electrolyte 250, the generated gas 260 may form gas bubbles 360 which, due to the density of the gas bubbles 360 being lighter than the density of the electrolyte 250, may naturally rise through the gap 340 towards and out of the top surface (e.g., second distal end) of the cathode-anode assemblies 212, as depicted by FIG. 2. Further, the flow of the electrolyte 250 through the gap 340 may assist in the rise of the gas bubbles 360 through and out of the gap 340.

In an example, the outlet tray 303 may receive the electrolyte 250 and the gas bubbles 360 from the cathode-anode assemblies 212 and provide the electrolyte 250 and the gas bubbles 360 to the gas collector 220, as depicted by FIG. 3. In another example, the capture tray 412 may receive the electrolyte 250 and the gas bubbles 360 from the cathode-anode assemblies 212. Further, the gas bubbles 360 may pop in the capture tray 412 and exit the gas generator 210 via the gas outlet tray 414, as depicted by FIG. 4.

During operation of the gas generator 210, an appropriate level of current density may need to be applied to each of the one or more cathode-anode assemblies 212 to produce an optimal amount of the gas 260 without introducing additional contaminants or impurities. The concentric cylindrical design of the cathode-anode assemblies 212 may allow the generation of the gas 260 (e.g., arsine) at a suitable rate for an MOCVD application based on a current density range. The current density range may be based on the rate of depletion of the first electrode layer 322 of the first electrode 320. Accordingly, a consistent rate of gas generation may be achieved by adjusting the electrical current supplied to the support rod 324 as the first electrode layer 322 is depleted. Further, the preservation of the concentricity of a cathode-anode assembly 212 may be achieved when the gap 340 maintains an equal distance during depletion of the first electrode layer 322.

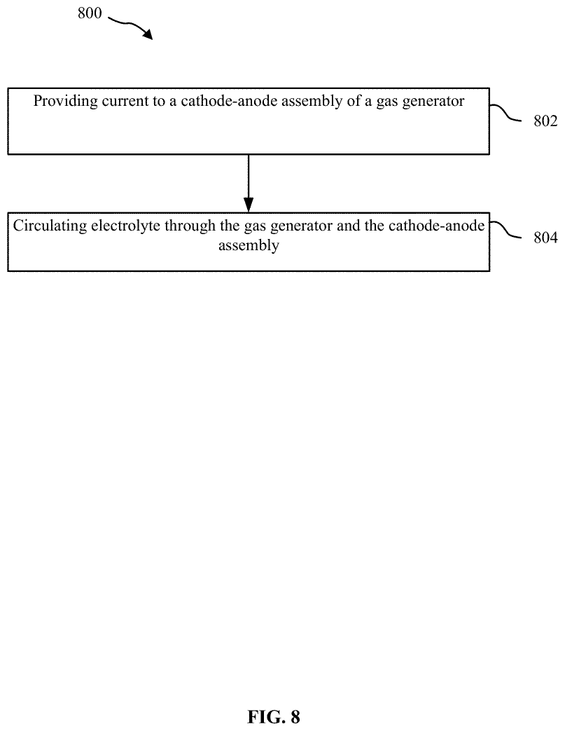

Referring to FIG. 8, an example of a method 800 for generating gas (e.g., arsine) by the gas generator 210 according to aspects of the present disclosure is illustrated. Various aspects of the method 800 may be controlled or coordinated by, for example, the controller 280, which may include one or more processors and/or one or more memories with instructions to coordinate the operations of the gas generator 210.

At 802, the method 800 may include providing an electrical current to a cathode-anode assembly of a gas generator. For example, the controller 280 may control the current source 270 to provide the electrical current to the one or more cathode-anode assemblies 212. In an example, the current source 270 may provide the electrical current to the first electrode 320.

At 804, the method 800 may include circulating electrolyte through the gas generator and the cathode-anode assembly. For example, the controller 280 may control the electrolyte circulation system 240 to circulate the electrolyte 250 through the gas generator 210 and the one or more cathode-anode assemblies 212. In an example, the controller 280 may control the pump 242 to circulate the electrolyte 250. The pump 242 may push the electrolyte 250 into the gap 340 via the base (e.g., first distal end) of the one or more cathode-anode assemblies 212 via the inlet tray 305. The electrolyte 250 may circulate through the gap 340 of the one or more cathode-anode assemblies 212 and exit the top (e.g., second distal end) of the one or more cathode-anode assemblies 212. The electrolyte 250 may then exit the gas generator 210 via the outlet tray 303 (or capture tray 412 depending on implementation).

It is understood that the specific order or hierarchy of blocks in the processes/flowcharts disclosed is an illustration of exemplary approaches. Based upon different implementations, it is understood that the specific order or hierarchy of blocks in the processes/flowcharts may be rearranged. Further, some blocks may be combined or omitted. The accompanying method claims present elements of the various blocks in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more.

Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.”

What is claimed is:

1. A gas generator comprising:
one or more current sources configured to generate an electrical current;
one or more cathode-anode assemblies electrically coupled with the one or more current sources and configured to generate a gas in response to receiving the electrical current from the one or more current sources, wherein each of the one or more cathode-anode assemblies comprises a first electrode and a second electrode forming a concentric cylindrical structure having a first opening and a second opening at distal ends of the concentric cylindrical structure, wherein the second electrode surrounds the first electrode and forms a gap between the second electrode and the first electrode, wherein the one or more cathode-anode assemblies are oriented in the gas generator for the gas to rise vertically through the gap from the first opening to the second opening; and
electrolyte configured to circulate through the gap of the one or more cathode-anode assemblies.

2. The gas generator of claim 1, wherein the first electrode is a sacrificial cathode and the second electrode is a sacrificial anode.

3. The gas generator of claim 1, wherein the first electrode is a sacrificial cathode and the second electrode is a hydrogen oxidation anode.

4. The gas generator of claim 1, wherein the first electrode comprises a support rod and a first electrode layer that surrounds the support rod.

5. The gas generator of claim 4, wherein the support rod is a cylinder formed of a conductive material.

6. The gas generator of claim 5, wherein the conductive material is steel, iron, stainless steel, or tungsten.

7. The gas generator of claim 4, wherein the first electrode layer is formed of elemental arsenic.

8. The gas generator of claim 1, wherein the second electrode is formed of an oxidizable metallic material.

9. The gas generator of claim 8, wherein the oxidizable metallic material includes one or more of molybdenum or tungsten.

10. The gas generator of claim 1, further comprising:
an electrolyte circulation system coupled with the one or more cathode-anode assemblies and configured to circulate the electrolyte through the one or more cathode-anode assemblies.

11. The gas generator of claim 10, wherein the electrolyte circulation system is further configured to maintain a composition of the electrolyte by adding one or more additives to the electrolyte or removing one or more contaminants from the electrolyte.

12. The gas generator of claim 1, wherein the gas is arsine gas.

13. A cathode-anode assembly configured to be implemented in a gas generator capable of holding the cathode-anode assembly, comprising:
a first electrode that forms a first elongated cylindrical structure; and
a second electrode that forms a second elongated cylindrical structure concentric with the first electrode, wherein a gap is formed between the second electrode and the first electrode,
wherein the gap allows circulation of electrolyte within the cathode-anode assembly, and gas is generated in the gap in response to an electrical current being applied to the cathode-anode assembly.

14. The cathode-anode assembly of claim 13, wherein the first electrode is a sacrificial cathode and the second electrode is a sacrificial anode.

15. The cathode-anode assembly of claim 13, wherein the first electrode is a sacrificial cathode and the second electrode is a hydrogen oxidation anode.

16. The cathode-anode assembly of claim 13, wherein the first electrode comprises a support rod and a first electrode layer that surrounds the support rod.

17. The cathode-anode assembly of claim 16, wherein the support rod is a cylinder formed of a conductive material.

18. The cathode-anode assembly of claim 16, wherein the first electrode layer is formed of elemental arsenic.

19. The cathode-anode assembly of claim 13, wherein the second electrode is formed of an oxidizable metallic material.

20. The cathode-anode assembly of claim 13, wherein the second electrode is configured to be electrically grounded.
